(19) United States
(12) Patent Application Publication
(10) Pub. No.: US 2002/0180630 A1
(43) Pub. Date: Dec. 5, 2002

(54) Electronic volume circuit

(75) Inventors: Hiroyuki Eguchi, Kanagawa-ken (JP); Mitsuru Nagata, Kanagawa-ken (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Tokyo (JP)

(21) Appl. No.: 10/096,666

(22) Filed: Mar. 14, 2002

(30) Foreign Application Priority Data
Mar. 15, 2001 (JP) P2001-074205

(51) Int. Cl. H03M 1/78

(52) U.S. Cl. 341/154

(57) ABSTRACT

An electronic volume circuit including a resistor circuit having a plurality of resistors connected in series and a plurality of switching circuits. Each switching circuit has a first transistor of a first conductivity type and a second transistor of a second conductivity type having a current path connected in parallel to said first transistor. Each switching circuit is connected between an output terminal of the electronic volume circuit and a corresponding connection node of the resistor circuit. Also, included is a decoder circuit configured to exclusively select one of the switching circuits, and a logic circuit configured to select one of the first and second transistors in the switching circuit selected by the decoder circuit during a testing operation.

### CROSS-REFERENCE TO A RELATED APPLICATIONS

This application claims the benefit of priority from prior Japanese Patent Application No. P2001-074205, filed on Mar. 15, 2001; the entire contents of which is incorporated herein by reference.

### FIELD OF THE INVENTION

The present invention relates to a volume mechanism applied to, for example, an audio system, and more particularly to an electronic volume circuit for use in applications from which a high quality is especially requested.

### BACKGROUND OF THE INVENTION

FIG. 1 illustrates a conventional electronic volume circuit. In FIG. 1, a plurality of resistors R1 to Rn are connected in series between a first terminal A and a second terminal B. A connection node N0 is provided between the first terminal A and the resistor R1, and a connection node Nn is provided between the resistor Rn and the second terminal B. Connection nodes N1 to Nn-1 are provided between the respective resistors R1 to Rn. A plurality of switching circuits SW0 to SWn are also respectively connected between the connection nodes N0 to Nn and an output terminal C. Among the switching circuits SW0 to SW4, one switching circuit (not shown) selected by a control signal is turned ON, and a potential at a connection node selected by this switching circuit is outputted to the output terminal C.

FIG. 2 illustrates an example of the switching circuits SW0 to SWn. Each of the switching circuits SW0 to SWn is formed by, for example, a P channel MOS transistor (hereinafter, referred to as a PMOS transistor) Tr1 and an N channel MOS transistor (hereinafter, referred to as an NMOS transistor) Tr2 which are connected in parallel. A control signal CS is supplied to a gate of the transistor Tr1 via an inverter circuit IV1, and a control signal CS is supplied to a gate of the transistor Tr2 via the inverter circuit IV1 and an inverter circuit IV2.

Furthermore, as shown in FIGS. 3A and 3B, the switching circuit is formed by only one PMOS transistor Tr3 or one NMOS transistor Tr4 depending on a particular use.

Next FIGS. 4A and 4B illustrate a current-voltage characteristic of a switching circuit formed by the transistors shown in FIGS. 3A and 3B, respectively. The characteristics represents a current between a terminal Nn of the switching circuit and a terminal C, which is obtained by supplying a reference voltage Vr to one terminal C, supplying a power source voltage VDD to a gate of the transistor, and by changing a potential at the terminal Nn from a ground potential GND to the power source voltage VDD.

In more detail, FIG. 4A illustrates a characteristic when the switching circuit is formed by the PMOS transistor shown in FIG. 3A, and FIG. 4B illustrates a characteristic when the switching circuit is formed by the NMOS transistor shown FIG. 3B. As described above, when the switching circuit is formed with the PMOS or NMOS transistor, the current-voltage characteristic shows a non-linear characteristic, resulting in a distortion effect as shown in FIGS. 4A and 4B. Therefore, it is not desirable to use this switching circuit in audio devices requiring a low distortion rate.

On the other hand, FIG. 4C illustrates a current-voltage characteristic of the switching circuit shown in FIG. 2 in which the PMOS and NMOS transistors are connected in parallel. In this case, a current output from the terminal C is equal to a sum of currents flowing through the PMOS and NMOS transistors as shown by the broken line of FIG. 4C and is close to a linear shape. Accordingly, it is preferable to use this switching circuit for a circuit requiring low distortion rate.

Mixed LSIs analog and digital circuits usually undergo a test performed by two stages before shipment. In many cases, a logic tester is used in the first stage test, and an analog tester is used in the second stage test. The logic tester tests characteristics of I/O terminals of the LSI by measuring a DC voltage and a DC current. Moreover, a digital circuit is tested by inputting a logic test pattern to check an output signal with an expected value. The analog tester measures an amplitude, a distortion rate and an S/N (signal vs. noise) ratio of an analog output signal to test an AC characteristic of the analog output signal. The test by the logic tester is called a DC test, and the test by the analog tester is called an AC test. In consideration of total test efficiency, it is desirable to reject defective articles in a test stage as early as possible.

Incidentally, when one transistor of the switching circuit shown in FIG. 2 is rendered in an open-circuit state because of a failure in manufacturing this transistor, the nonlinear characteristics as shown in FIGS. 4A and 4B appear. For this reason, a phenomenon occurs in which a distortion rate of an output is deteriorated in spite of a normal attenuation amount. When a short-circuit failure occurs in the switching circuit, the attenuation amount clearly deviates from a normal value. Therefore, the short-circuit failure of the switching circuit can be easily detected in the DC test.

Specifically, in the DC test, a potential difference is applied between both terminals of the resistor of a volume mechanism, and a DC potential output is measured while sequentially turning ON switches in the volume. Then it is confirmed whether or not the attenuation amount is set normally based on the measured DC potential, whereby the short-circuit failure of the switching circuit can be detected.

However, it is difficult to detect the open circuit failure of the switching circuit using the DC test. Specifically, when both of the PMOS and NMOS transistors show the open-circuit failure, an original attenuation amount cannot be obtained. Therefore, the open circuit failure of both transistors can be detected. However, when the open-circuit failure occurs in only one transistor, a measurement result approximately equal to a predetermined attenuation amount can be obtained. Therefore, when the open-circuit failure occurs in only one transistor, a switching circuit causing the failure cannot be detected by measuring only the attenuation amount. Consequently, such a failure must be rejected by the AC test.

In the AC test, a sine wave signal is supplied to a volume mechanism, and a distortion rate of an output signal from the volume is measured, whereby a switching circuit causing an open-circuit failure can be detected. However, the measurement of the distortion rate using the AC test requires a longer time compared to a voltage measurement of the DC test. Therefore, it is desirable to use the DC test to reject the switching circuit having an open-circuit failure.

As described above, when the open-circuit failure occurs in only one transistor, the switching circuit passes the DC test. Accordingly, because a defective is AC tested, test efficiency is lowered.

On the other hand, in a volume mechanism used in audio devices and the like, the amount of the attenuation is represented by dB, and display intervals are set in equal steps. Because this dB displaying has a logarithmic characteristic, a change rate of a resistance value in a range where the attenuation amount is large is smaller than that in a range where the attenuation amount is small. Accordingly, when an attenuation rate of the resistor is measured by the DC test, a change of a DC current outputted from the output terminal of the volume is smaller in the range where the attenuation amount is large. Therefore, it is difficult to directly measure the DC current outputted, and a circuit optionally attached thereto such as an amplifier is needed,. This increases the costs of performing the test operations.

### BRIEF SUMMARY OF THE INVENTION

Accordingly, one object of the present invention is to solve the above-noted and other problems.

To achieve this and other objects, the present invention provides a novel electronic volume circuit including a resistor circuit having a plurality of resistors connected in series, and a plurality of switching circuits. Each of the switching circuits has a first transistor of a first conductivity type and a second transistor of a second conductivity type having a current path connected in parallel to the first transistor and is connected between an output terminal of the electronic volume circuit and a corresponding connection node of the resistor circuit. Also included is a decoder circuit configured to exclusively select one of the switching circuits, and a logic circuit configured to select one of the first and second transistors in the switching circuit selected by the decoder circuit during a testing operation.

### BRIEF DESCRIPTION OF THE DRAWINGS

A more complete appreciation of embodiments of the present invention and many of its attendant advantages will be readily obtained by reference to the following detailed description considered in connection with the accompanying drawings, in which:

FIG. 1 is a circuit diagram illustrating an example of a conventional electronic volume;

FIG. 2 is a circuit diagram illustrating an example of a switching circuit shown in FIG. 1;

FIGS. 3A and 3B are circuit diagrams illustrating other examples of the switching circuit shown in FIG. 1;

FIGS. 4A to 4C are graphs illustrating examples of current-voltage characteristics of the switching circuits shown in FIGS. 2 and 3A-3B;

FIG. 5 is a circuit diagram illustrating an example of a first embodiment of the present invention;

FIG. 6 is a circuit diagram illustrating an example of a volume mechanism shown in FIG. 5;

FIG. 7 is a circuit diagram illustrating an example of a logic circuit for controlling operations of switching circuits in the volume mechanism shown in FIG. 6 and transistors forming the switching circuits;

FIG. 8 is a logical value table illustrating an example of an operation of the circuit shown in FIG. 5;

FIG. 9 is a circuit diagram illustrating an example of a reference voltage generation circuit for generating a reference voltage shown in FIG. 5;

FIG. 10 is a circuit diagram illustrating an example of a decoder shown in FIG. 5;

FIG. 11 is a circuit diagram illustrating an example of a second embodiment of the present invention;

FIG. 12 is a circuit diagram illustrating an example of an operational amplifier shown in FIG. 11.

FIG. 13 is a table illustrating an example of resistance values of the volume mechanism;

FIG. 14 is a circuit diagram illustrating an example of a volume mechanism in a third embodiment of the present invention;

FIG. 15 is a circuit diagram illustrating an example of a fourth embodiment of the present invention;

FIG. 16 is a circuit diagram illustrating an example of the volume mechanism shown in FIG. 15;

FIG. 17 is a circuit diagram illustrating an example of a logic circuit for controlling operations of switching circuits in the volume mechanism shown in FIG. 15 and transistors forming the switching circuits;

FIG. 18 is a logical value table illustrating an example of operations of the circuits shown in FIGS. 16 and 17; and

FIG. 19 is a circuit diagram illustrating an example of a clock inverter circuit.

### DETAILED DESCRIPTIONS OF THE EMBODIMENTS

Embodiments of the present invention will now be described with reference to the accompanying drawings below.

### First Embodiment

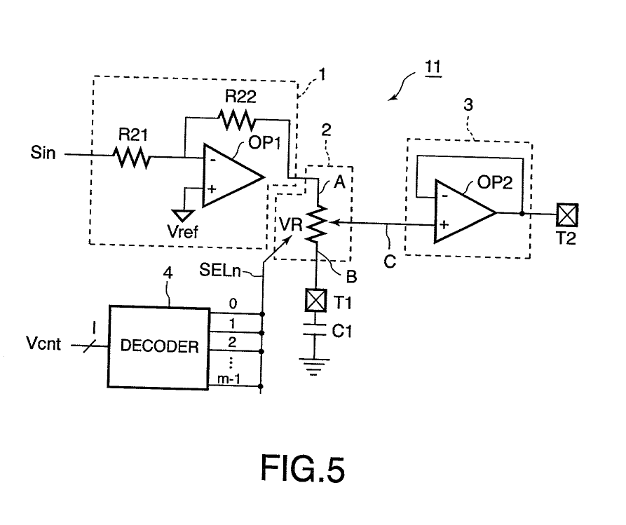

FIG. 5 illustrates a first embodiment according to an electronic volume circuit of the present invention. In FIG. 5, an electronic volume circuit 11 is formed by an amplifying circuit 1, a volume mechanism 2, a voltage follower circuit 3 and a decoder 4. The amplifying circuit 1 is formed by an operational amplifier (hereinafter, referred to as an op-amp) OP1 and resistors R21 and R22. An input signal Sin is supplied to an inverting input terminal of the op-amp OP1 via the resistor R21. A reference voltage Vref is supplied to a non-inverting input terminal of the op-amp OP1. Further, an output terminal of the op-amp OP1 is connected to the inverting input terminal via the resistor R22.

Furthermore, the output terminal of the op-amp OP1 is connected to a first terminal A of the volume mechanism 2, and a second terminal B of a volume mechanism 2 is connected to an external connection terminal T1. A capacitor C1 is connected between the external connection terminal T1 and the ground. Therefore, the external connection terminal T1 is grounded via the capacitor C1 in an AC manner.

Also, an output terminal C of the volume mechanism 2 is connected to a non-inverting input terminal of an op-amp OP2 forming the voltage follower 3. An output terminal of the op-amp OP2 is connected to an external connection terminal 2 as well as to an inverting input terminal of the op-amp OP2.

The decoder 4 decodes one-bit control input data Vcnt representing an attenuation amount, and outputs m pieces of control signals, each of which turns ON a corresponding one of a plurality of switching circuits forming the volume mechanism 2. For example, in the case of a 16-step volume, “1” is equal to 4, and “m” is equal to 16.

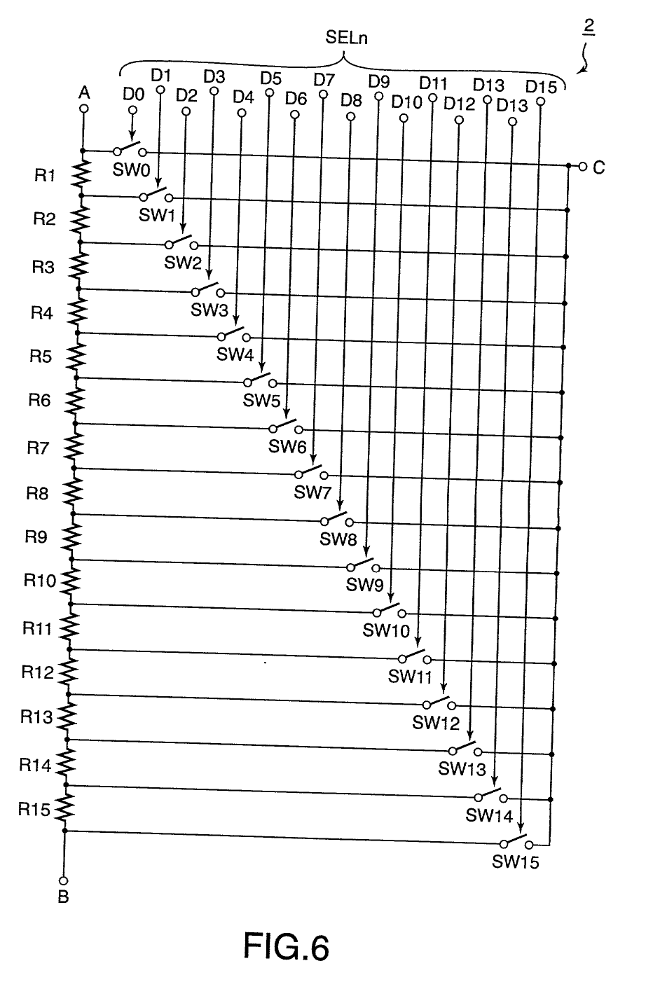

FIG. 6 illustrates an example of the volume mechanism 2. The volume 2 mechanism includes a resistor circuit having 15 resistors R1 to R15 connected in series between the first and second terminals A and B, and switching circuits SW0 to SW15. The switching circuits SW0 to SW15 are sequentially connected between a terminal C and respective connection nodes of the first terminal A, the resistors R1 to R15 and the second terminal B. Respective control signals D0 to D15 outputted from the decoder 4 select one of the switching circuits SW0 to SW15.

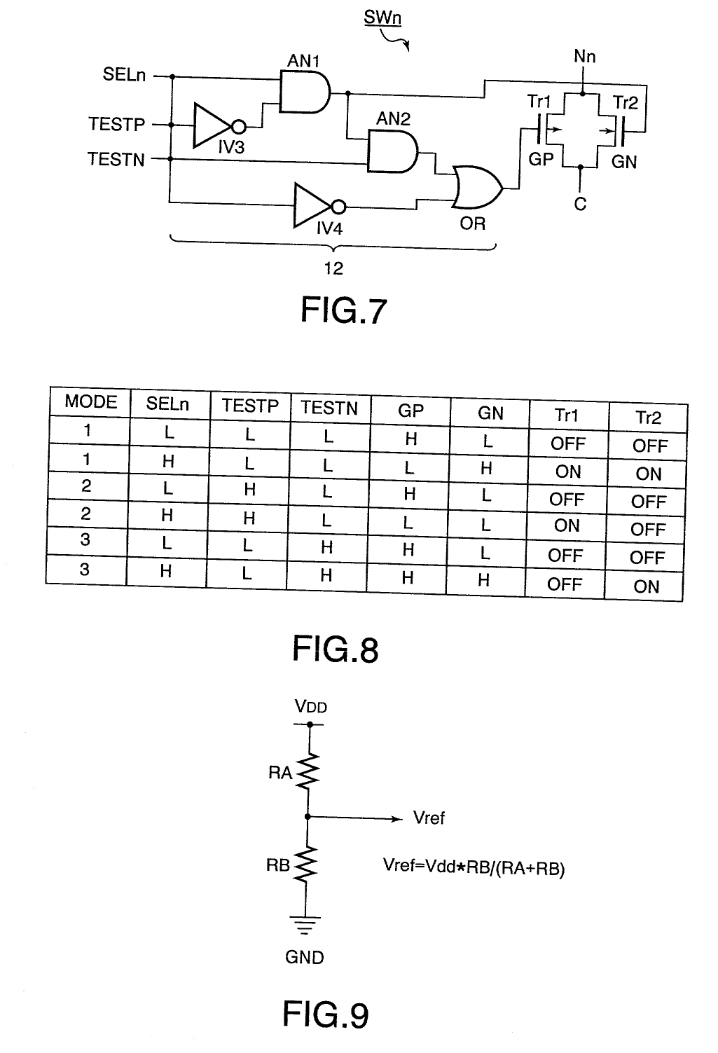

FIG. 7 illustrates an example of a logic circuit for performing selective control operations for the switching circuits SW0 to SW15 and for the transistors forming the respective switching circuits. The switching circuit SWn (n=0 to 15) is formed so a PMOS transistor Tr1 and an NMOS transistor Tr2 are connected in parallel to each other between the connection node Nn of the resistor circuit and the output terminal C. The output terminal C is connected to the non-inverting input terminal of the op-amp OP2 shown in FIG. 5.

The switching circuit SWn including the transistors Tr1 and Tr2 is controlled by the logic circuit 12. The logic circuit 12 is formed by, for example, AND circuits AN1 and AN2, inverter circuits IV3 and IV4 and an OR circuit OR.

One selection signal SELn outputted from the decoder 4 is applied to an input terminal of the AND circuit AN1. A selection signal TESTP is supplied to the other input terminal of the AND circuit AN1 via the inverter circuit IV3. In addition, the selection signal TESTP is the one for selecting the PMOS transistor Tr1 during the test. An output signal of the AND circuit AN1 is supplied to a gate GN of the foregoing NMOS transistor Tr2 as well as to one input terminal of the AND circuit AN2. A selection signal TESTN is supplied to the other input terminal of the AND circuit AN2. The selection signal TESTN is the one for selecting the NMOS transistor Tr2 during the test. Further, an output signal from the AND circuit AN2 is supplied to one input terminal of the OR circuit OR. The selection signal SELn is supplied to the other input terminal of this OR circuit via the inverter circuit IV4, and an output signal from the OR circuit OR is supplied to a gate GP of the PMOS transistor Tr1.

During a normal operation, only one selection signal SELn exclusively select among n selection signals SELn is rendered high in level, and the other selection signals are rendered low in level. Furthermore, both of the selection signals TESTP and TESTN are rendered low in level. Accordingly, a gate potential of the PMOS transistor Tr1 of the switching circuit selected by the selection signal SELn is rendered low in level, that is, equal to a ground potential GND, and a gate potential of the NMOS transistor Tr2 is rendered high in level, that is, equal to a power source voltage VDD. Therefore, both of the transistors Tr1 and Tr2 are turned ON.

Furthermore, a gate potential of the PMOS transistor of the switching circuit nonselected becomes high in level and a gate potential of the NMOS transistor becomes low in level. These transistors have an open-circuit state.

On the other hand, when the PMOS transistor is tested during the test of the switching circuit, the selection signal TESTP is rendered high in level, and the selection signal TESTN is rendered low in level. In this state, a control operation is performed so all of the switching circuits other than that selected by the selection signal SELn are made to be in an open-circuit state and only a PMOS transistor of the selected switching circuit is made to be in a turning-ON state. Specifically, gate potentials of the PMOS and NMOS transistors Tr1 and Tr2 are rendered low in level by the selection signals SELn, TESTP and TESTN. Therefore, the PMOS transistor Tr1 has a turning ON state, and the NMOS transistor Tr2 has an open-circuit state.

Furthermore, when the NMOS transistor is tested, the selection signal TESTP is rendered low in level, and the selection signal TESTN is rendered high in level in this state, all of the switching circuits other than the switching circuit selected by the selection signal SELn are made to be in an open-circuit state, and only the NMOS transistor of the selected switching circuit is controlled so as to be in a turning ON state. Specifically, gate potentials of the PMOS and NMOS transistors Tr1 and Tr2 are rendered high in level by the selection signals SELn, TESTP and TESPN. Therefore, the PMOS transistor Tr1 falls has an open circuit state, and the NMOS resistor Tr2 has a turning ON state.

In the above-described manner, the potential of the signal outputted from the switching circuit is measured, and a shift of the attenuation amount is detected, whereby the PMOS transistor Tr1 and the NMOS transistor Tr2 can be individually tested.

Turning now to FIG. 8, which is a logical value table showing a relationship between each of the selection signals SELn, TESTP and TESTN and the gate potential of each of the PMOS and NMOS transistors. In this table, a normal operation mode is represented as a mode 1; a test mode of the PMOS transistor is represented as a mode 2; and a test mode of the NMOS transistor is represented as a mode 3.

In an actual test, the electronic volume circuit illustrated in FIG. 5 is set as follows. Specifically, the external connection terminal T1 is grounded via the capacitor C1 during a normal operation. However, during the test, an arbitrary voltage, for example, a power source voltage VDD, is applied to the external connection terminal T1. Moreover, an amplitude of the input signal Sin of the amplifier circuit 1 is made zero, and an output voltage of the operational amplifier OP1 is fixed to the reference voltage Vref. As a result, a potential difference equal to VDD−Vref is applied to both terminals of the volume mechanism 2, and a potential of the connection node selected by the control input data Vcnt of the volume mechanism is outputted from the external connection terminal T2.

In this state, the selection signal TESTP is rendered high in level, and the selection signal TESTN is rendered low in level. A potential of the external connection terminal 2 is measured while changing each value of the control input data Vcnt which the control input data Vcnt can take.

Next, the selection signal TESTP is rendered low in level, and the selection signal TESTN is rendered high in level. The potential of the external connection terminal T2 is measured while changing each value of the control input data Vcnt which the control input data Vcnt can take. By measuring the potential of the external connection terminal T2 in the above described manner, the open-circuit failures, the short-circuit failure and the shift of the resistance value of all transistors forming the switching circuit can be detected.

FIG. 9 illustrates an example of a reference voltage generation circuit that generates the reference voltage Vref shown in FIG. 5. This reference voltage generation circuit includes resistors RA and RB connected in series between a terminal supplied with the power source voltage VDD and the ground. The reference voltage Vref is outputted, which is generated by dividing the power source voltage VDD using a connection node of the resistors RA and RB. The reference voltage Vref is expressed by the following equation.

Vref=VDD×RB/(RA+RB).

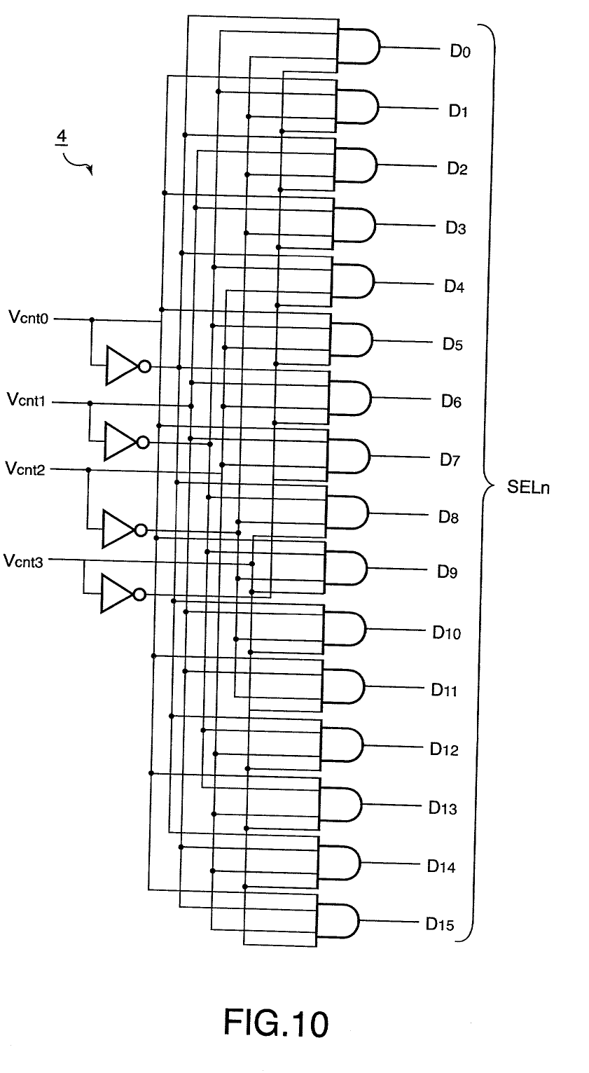

Next FIG. 10 illustrates an example of the decoder 4 shown in FIG. 5. This example illustrates the decoder which is applied to a 16-step volume. This decoder 4 outputs 16 selection signals D0 to D15 (SELn) in response to four-bit control input data Vcnt0 to Vcnt3. A concrete circuit forming the decoder 4 is not limited to the circuit illustrated in FIG. 10.

Furthermore, if the input signal Sin of the amplifier circuit 1 shown in FIG. 5 can be fixed to a potential such as the ground potential and the power source voltage VDD, the output potential of the amplifier circuit 1 can be set to a potential other than the reference voltage Vref. For example, if the input signal Sin is set to the ground potential, the output voltage of the amplifier circuit 1 is equal to Vref+Vref×R22/R21, and a large potential difference between both terminals of the volume 2 can be set. As the potential difference between the both terminals of the volume 2 is larger, a magnitude of a variation of the output voltage when the volume is changed becomes larger. Therefore, the failure detection becomes easier. Note that when a gain R22/R21 of the amplifier circuit 1 is lower than 1, the output of the amplifier circuit 1 does not reach the power source voltage VDD.

According to the first embodiment, it is possible to select one of the PMOS and NMOS transistors Tr1 and Tr2 forming the switching circuit SWn by switching the selection signal SELn outputted from the decoder 4 and the selection signals TESTP and TESTN. Therefore, it is possible to test the short-circuit state and the open-circuit state of the PMOS and NMOS transistors Tr1 and Tr2 separately. In addition, because this test is the DC test, the test is simple, and the time required for the test is short. Accordingly, a test efficiency is improved.

Furthermore, because the failure of the switching circuit can be determined by the DC test, an electronic volume circuit having a failure can be removed beforehand. Accordingly, it is possible to enhance the efficiency of the AC test and improve the yield of the electronic volume circuits.

### Second Embodiment

Next a second embodiment of the present invention will be described.

The electronic volume circuit shown in the first embodiment shows a small difference of the attenuation amount because a difference of the resistance value between the resistors adjacent to each other is small in a range where the attenuation amount is large. Therefore, a measurement apparatus having a high resolution is necessary for detecting the failure of the transistor forming the switching circuit.

Accordingly, if a predetermined reference voltage is applied to both terminals of the volume mechanism so the reference voltage is outputted when any switching circuit is turned ON, a high resolution is not required to detect the open-circuit failure.

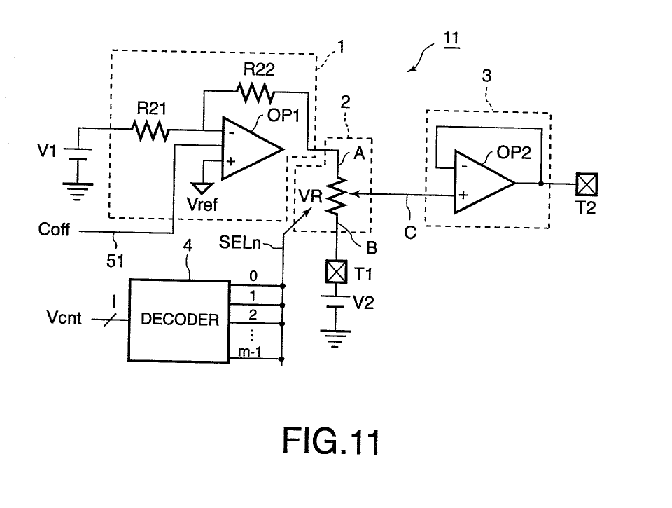

FIG. 11 illustrates the second embodiment. The same components as those of FIG. 5 are denoted by the same reference numerals and symbols, and accordingly descriptions will be made for only the different components.

As shown, an op-amp OP1 forming an amplifier circuit 1 has an input terminal 51. A control signal Coff is supplied to this input terminal 51. The control signal Coff is the one which is made low in level during a normal operation and made high in level during the test.

During the test, an output terminal of the op-amp OP1 is set to a high impedance state by the control signal Coff. At the same time, a voltage V1 is supplied to an inverting input terminal of an amplifier circuit 1 via a resistor R21, and a voltage V2 is supplied to an external connection terminal T1. Because the output terminal of the op-amp OP1 is in the high impedance state, the voltages V1 and V2 are supplied to both terminals of a series circuit including resistors R21 and R22 and the volume mechanism 2.

For example, when the voltages V1 and V2 are made equal to VDD and the volume mechanism 2 is in a normal state, all potentials at each of connection nodes of the resistors forming the volume mechanism 2 are equal to VDD. Therefore, when there is no failure in a switching circuit of the volume mechanism 2, a potential of an output terminal T2 is equal to VDD even if any connection node of the resistor circuit is selected by the switching circuit. Accordingly, if the PMOS and NMOS transistors are individually turned ON for each of the switching circuits of the volume mechanism 2 and the potential of the output terminal T2 is measured, the open-circuit failures of all transistors can be detected.

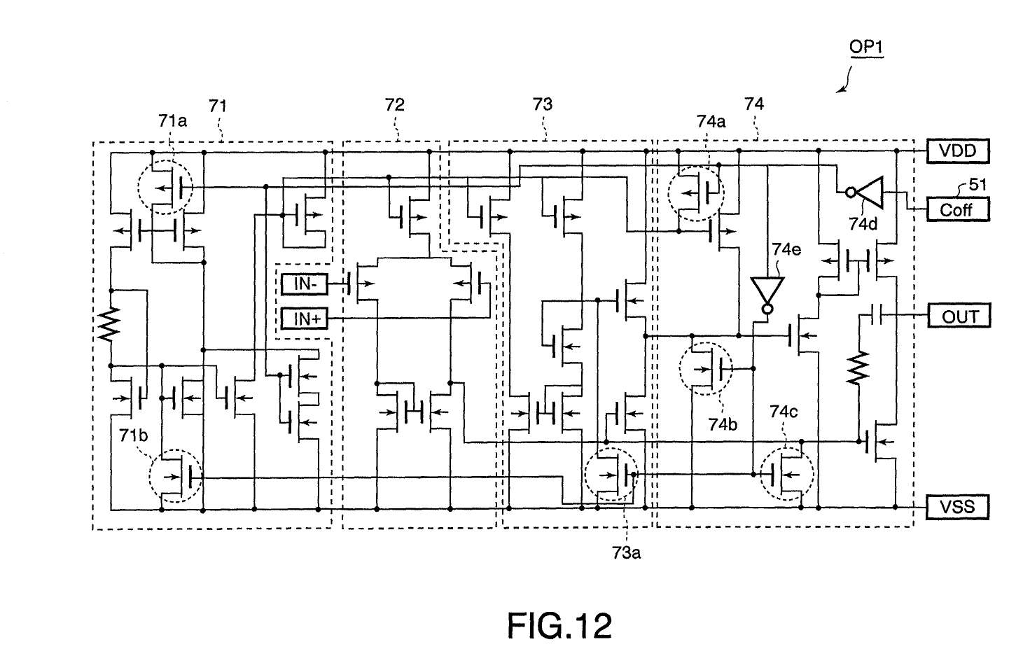

FIG. 12 illustrates an example of the op-amp OP1. As shown, the op-amp OP1 includes a current source circuit 71, a differential input circuit 72 having an inverting input terminal and a non-inverting input terminal, a bias generation circuit 73 for generating a bias for an output circuit, and the output circuit 74 for outputting a signal in accordance with a signal supplied to its input terminal. A control signal Coff supplied to the input terminal 51 is supplied to a gate of a PMOS transistor 74a provided in the output circuit 74 and a gate of a PMOS transistor 71a provided in the current source circuit 71 via an inverter circuit 74d. At the same time, the control signal Coff is supplied to gates of NMOS transistors 74b and 74c provided in the output circuit 74 via the inverter circuit 74d and an inverter circuit 74e, a gate of an NMOS transistor 73a provided in the bias generating circuit 73, and a gate of an NMOS transistor 71b provided in the current source circuit 71.

The control signal Coff is made low in level during a normal operation and high in level during the test. Therefore, during the test, all of the transistors 71a, 71b, 73a, 74a; 74b and 74c are turned ON. Accordingly, operations of the current source circuit 71, the bias generating circuit 73 and the output circuit 74 are stopped, and an output terminal OUT is made to be high in impedance.

According to the second embodiment, during the test, a predetermined potential, for example, the power source voltage VDD, is supplied to both terminals of the volume mechanism 2, and all potentials of connection nodes of the resistors forming the volume mechanism 2 are set to VDD. Therefore, because a voltage outputted from any of the selected switching circuits is equal to VDD when the switching circuits are switched, it is possible to measure the open-circuit state of the PMOS and NMOS transistors forming the switching circuit without using a high resolution measurement instrument. Accordingly, a test cost can be reduced.

Furthermore, the op-amp OP1 has an input terminal for receiving the control signal Coff, and the output terminal thereof is made high in impedance during the test by the control signal Coff. Accordingly, it is possible to easily set the both terminals of the volume mechanism 2 to a predetermined potential during the test.

### Third Embodiment

Next, a third embodiment of the present invention will be described.

As described above, when the attenuation amount is represented by dB and equal display intervals are set, a change rate of a resistance value in a range where the attenuation amount is large is smaller than that in a range where the attenuation amount is small. Accordingly, a change of a DC potential outputted from the output terminal of the volume is small in the DC test in a range where the attenuation amount is large. Therefore, when an attenuation rate of the resistor was measured, a measurement instrument having a high resolution was necessary.

In the 16-step volume mechanism 2 shown in FIG. 6, when a total resistance value is assumed to be R and this resistance R is divided by a certain attenuation rate α, (the resistance value Rn of the n-th resistor is expressed by the equation (1).

Rn=(1−α)×αⁿ⁻¹×R (1)

When the attenuation amount is set from 0 dB to −∞ in 1 dB steps is considered, R1 to R14 can be determined by the equation (1), and R15 is equal to a value obtained by subtracting a sum of R1 to R15 from the total resistance value R.

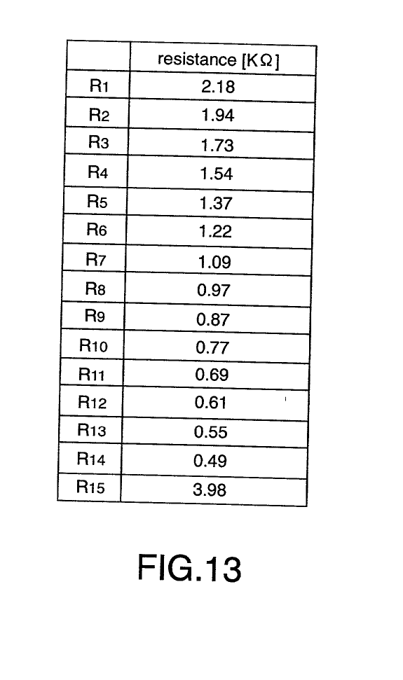

FIG. 13 shows concrete resistance values when the total resistance value of the volume mechanism 2 is set to, for example, R=20kΩ and α is set to 0.891 (1 dB step).

When a potential difference is applied to both terminals of the volume mechanism 2 by the formation shown in the first embodiment, an output voltage Vout (k) when the k-th switching SWk is turned ON is represented by the equation (2).

Vout (k)=V×α^{k} (2)

Furthermore, the magnitude ΔVout (k) of the change of the output potential when the turning-ON state of the k-th switching circuit SWk is brought about from the turning-ON state of the (k−1)-th switching circuit SWk−1 is represented by the equation (3).

ΔVout (k)=V×α^{k-1}−V×α^{k}=V×(1−α)×α^{k-1} (3)

For example, when a potential of a first terminal A in the volume mechanism 2 shown in FIG. 6 is set to VDD of 3.3 V and a potential of a second terminal B therein is set to the ground level, when the turning-ON state of the switching circuit SW14 is brought about from the turning-ON state of the switching circuit SW13, the magnitude ΔVout (14) of the change of the output potential is represented by the equation (4).

$$\begin{matrix}Δ Vout ( 14 ) = 3.3 \times ( 1 - 0.891 ) \times {0.891}^{13} \\ = 80 ( mV )\end{matrix} \qquad ( 4 )$$

Furthermore, when the number of the dividing steps of the resistors is expanded to 48 steps and then switching from the switching circuit SW45 to the switching circuit SW46 is made, the magnitude ΔVout of the change of the output voltage becomes a minimum. This magnitude ΔVout (46) of the change is expressed by the equation (5).

$$\begin{matrix}Δ Vout ( 46 ) = 3.3 \times ( 1 - 0.891 ) \times {0.891}^{45} \\ = 2.0 ( mV )\end{matrix} \qquad ( 5 )$$

For example, when the attenuation rate is set to a precision of 10%, 10% of the magnitude ΔVout (46), which is equal to 2.0 mV, of the change of the output voltage, that is, a measurement resolution of 0.2 mV, is required during the test. However, because a measurement instrument is influenced by power source noise, a contact resistance and a wiring resistance, it is difficult to obtain the foregoing measurement resolution in many cases.

Accordingly, the third embodiment makes it possible to measure the attenuation rate of the resistor without using a measurement instrument having a high precision resolution.

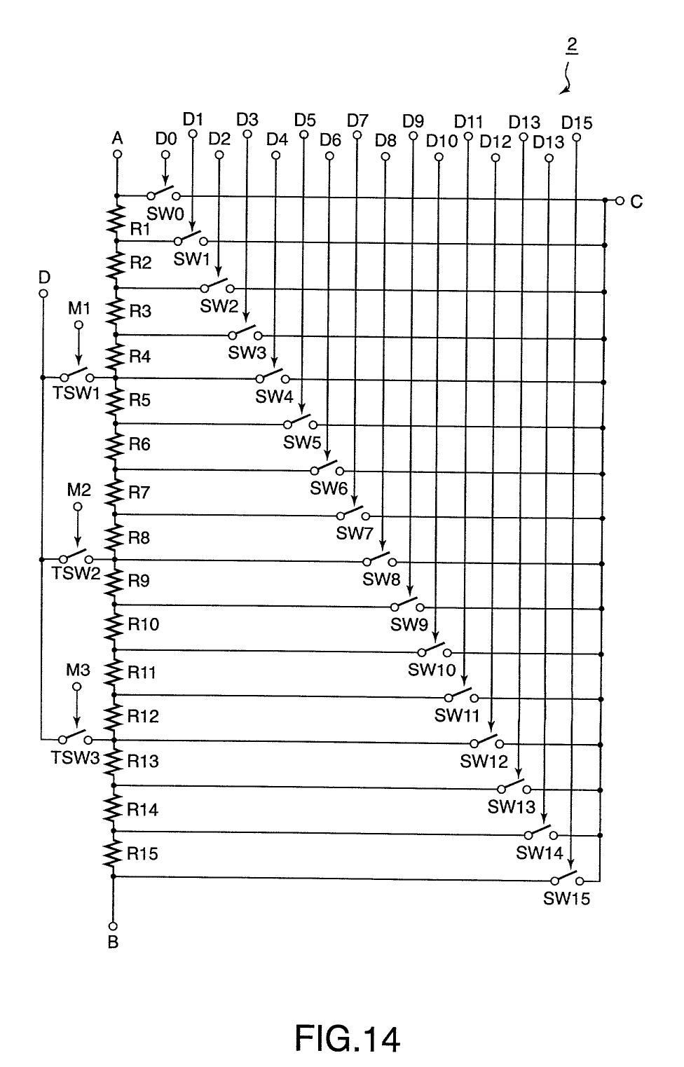

FIG. 14 illustrates a formation the volume mechanism applied to the third embodiment. The same components as those of FIG. 6 are denoted by the same reference numerals and symbols, and accordingly descriptions will be made only for the different components.

In FIG. 14, test switching circuits TSW1, TSW2 and TSW3 are provided in respective connection nodes disposed between the first and second terminals A and B of the volume mechanism 2, and the connection nodes are set to arbitrary potentials by the switching circuits TSW1, TSW2 and TSW3. Specifically, the switching circuit TSW1 is connected between a third terminal D and the connection node of the resistors R4 and R5, and the switching circuit TSW2 is connected between the third terminal D and the connection node of the resistors R8 and R9. Moreover, the switching circuit TSW3 is connected between the third terminal D and the resistors R12 and R13. The switching circuits TSW1, TSW2 and TSW3 are controlled by control signals M1, M2 and M3, respectively. A potential, for example, the power source voltage VDD, which is equal to a potential supplied to the first terminal A, is supplied to the third terminal D.

The switching circuits TSW1, TSW2 and TSW3 are switched depending on a position of a switching circuit to be tested. In more detail, during the test time from the switching circuit SW0 to the switching circuit SW5, all of the test switching circuits TSW1 to TSW3 are allowed to be turned OFF. During the test tine from the switching circuit SW4 to the switching circuit SW9, only the test switching circuit TSW1 is allowed to be turned ON. Next, when the test is performed from the switching circuit SW8 to the switching circuit SW13, only the test switching circuit TSW2 is allowed to be turned ON. Further, when the test is performed from the switching circuit SW12 to the switching circuit SW15, the test switching circuit TSW3 is turned ON. In each test range, the reason why the adjacent switching circuits are overlapped is because the overlap of the switching circuit is necessary for measuring a ratio of the attenuation amount by switching the switching circuit.

When the test is performed by switching the test switching circuits TSW1 to TSW3 in the above described manner, the minimum value of the magnitude of the change of the output potential in each test range is expressed by the equation (6).

$$\begin{matrix}Δ Vout ( 5 ) = 3.3 \times ( 1 - 0.891 ) \times {0.891}^{4} \\ = 227 ( mV )\end{matrix} \qquad ( 6 )$$

As described above, the minimum value of the magnitude of the change of the output potential becomes smaller than those of the equations (4) and (5). Therefore, the resolution of the measurement instrument can be relaxed.

Also, when the number of the steps is expanded from those of the circuit shown in FIG. 14, the test can be performed with the same measurement resolution as described above by connecting the test switching circuit, for example, every four resistors.

According to the third embodiment, the test switching circuits TSW1 to TSW3 are respectively connected between the plurality of connection nodes and the third terminal D. The plurality of connection nodes are disposed in the middle of the resistors R1 to R15 connected in series, and a predetermined potential is applied to the third terminal D. The test switching circuits TSW1 to TSW3 are switched in accordance with the test range for the switching circuits. Therefore, the minimum value of the change of the output voltage, which is outputted in each test range of the switching circuits, can be made large. Accordingly, it is possible to accurately measure the attenuation rate of the resistor without using a measurement instrument having a high resolution, an amplifier and the like.

### Fourth Embodiment

Next, a fourth embodiment of the present invention will be described.

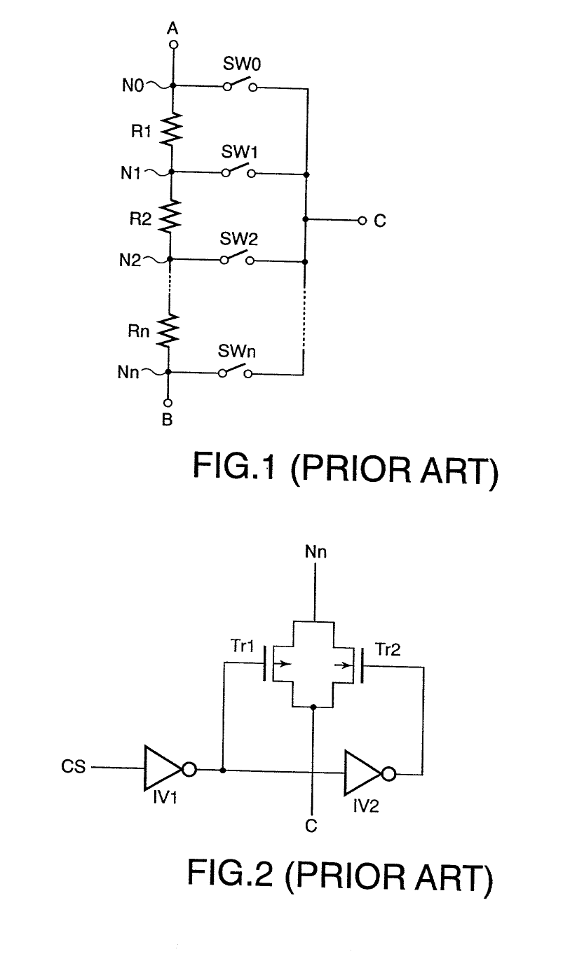

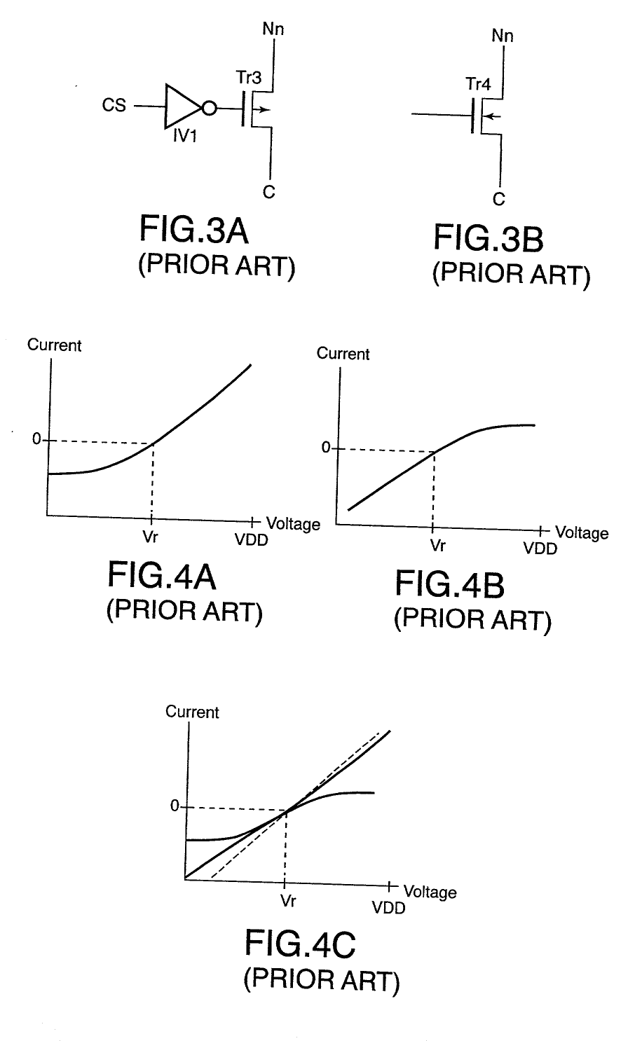

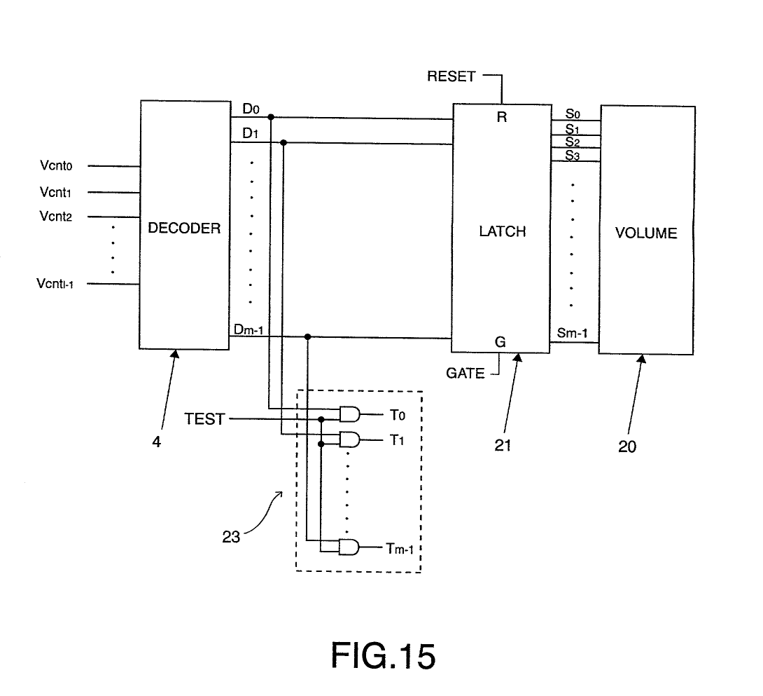

FIG. 15 is a block diagram illustrating the fourth embodiment, and components different from the electronic volume circuit of the first embodiment shown in FIG. 5 are selectively illustrated. The same components as those in FIG. 1 are hereinafter denoted by the same reference numerals and symbols.

A decoder circuit 4 decodes one bit control input data Vcnt representing the attenuation amount similarly to the first embodiment, and outputs m pieces of selection signals SELn (n=0 to (m−1)) for turning ON one of a plurality of switching circuits SWn constituting a volume 20 to be described later. For example, in the case of a 16-step volume, “1” is 4, and “m” is 16.

In an example of the fourth embodiment, a latch circuit 21 is provided between the decoder circuit 4 and a volume circuit 20, and the latch circuit 21 latches once m pieces of selection signals SELn outputted from the decoder circuit 4. Then, the latch circuit 21 outputs latch signals Sn to the volume circuit 20 alter arranging output timings of the latch signals Sn based on the selection signals SELn.

The latch circuit 21 is formed so as to hold an output until a value of a gate signal inputted to a latch gate terminal G is a low level “L” and so as to update the output when the value thereof is a high level “H”. A changing timing of a value of the gate signal is set so the value of the gate signal becomes a high level at a timing when all values of m pieces of selection signals SELn outputted from the decoder circuit 4 are decided. Thus, after all values of m pieces of selection signals SELn are decided, m pieces of output signals Sn outputted from the latch circuit 21 based on the selection signals SELn are outputted to the volume circuit 20 from the latch circuit 21 without being influenced by a transient state change when m pieces of selection signals SELn are outputted from the decoder 4.

Further, a latch reset terminal R is provided in the latch circuit 21. The latch circuit 21 is formed so when a reset signal is inputted to the terminal R from the outside, the latch circuit 21 renders all outputs low in level irrespective of values of the output signals from the decoder circuit 4 and outputs them. This reset signal is used as a selection signal for selecting one of the PMOS and NMOS transistors Tr1 and Tr2 when the test is performed.

Furthermore, a logic circuit 23 including m pieces of AND circuits ANn (n=0 to (m−1)) is provided in the rear stage of the decoder circuit 4. A test mode selection signal TEST is inputted to one input terminal of each of the AND circuits ANn, and the selection signals SELn outputted from the decoder circuit 4 are respectively inputted to the other input terminals of the corresponding AND circuits ANn. Selection signals Tn are respectively outputted based on a logical product (AND) of these signals. Control clocks φn (=//Tn), /φn (=/Tn) for controlling a clocked inverter circuits CIV12 and CIV13 to be described later are generated based on the value of the selection signal Tn.

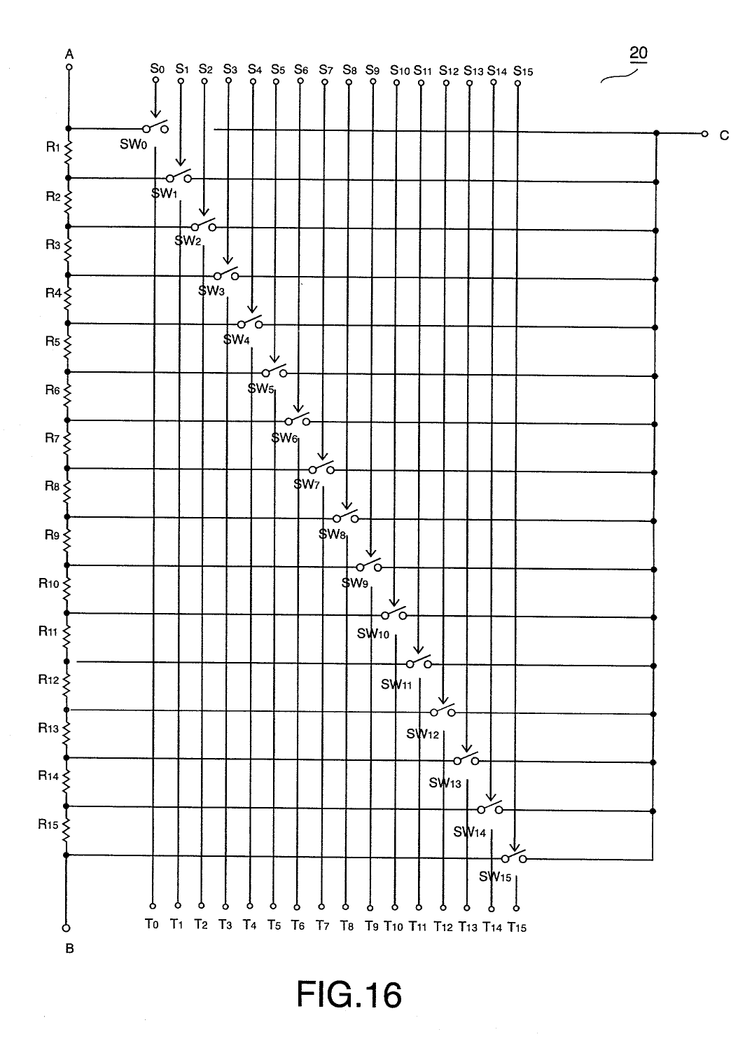

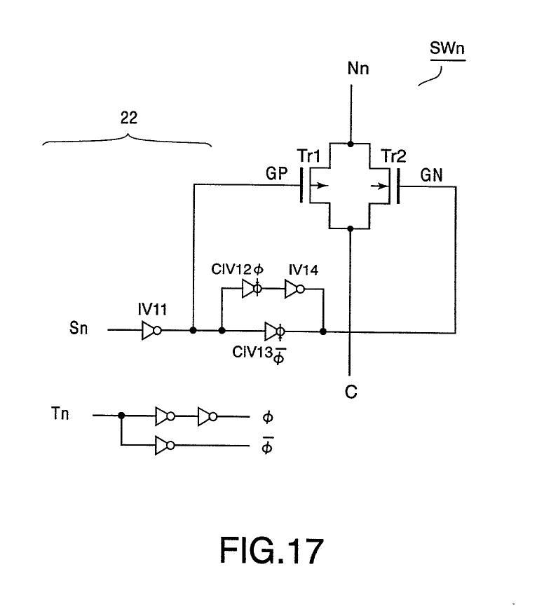

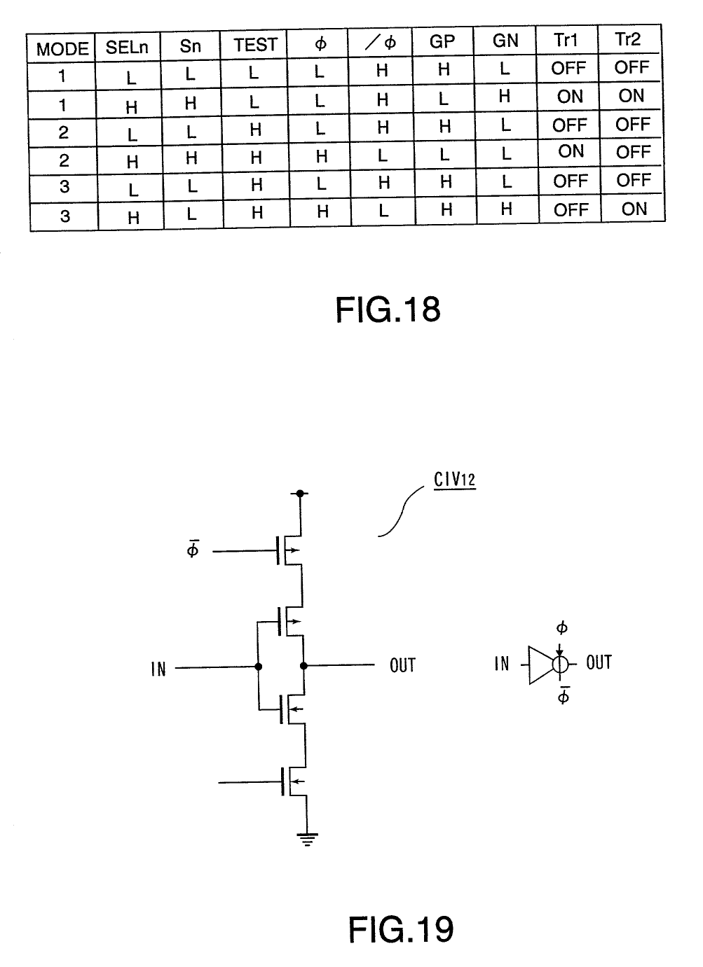

Turning now to FIG. 16, which illustrates an example of the volume circuit 20. Moreover, FIG. 17 illustrates an example of the switching circuit SWn and a logic circuit for controlling selective operations of the transistors forming the switching circuit. FIG. 18 is a logical value table showing the operations of the circuits shown in FIGS. 16 and 17. A normal operation mode is represented as a mode 1; a test mode of the PMOS transistor is represented as a mode 2; and a test mode of the NMOS transistor is represented as a mode 3.

The volume circuit 20 includes a resistor circuit having 15 resistors R1 to R15 connected in series between first and second terminals A and B, and switching circuits SW0 to SW15, each of which is connected between a terminal C and corresponding connection node of the first and second terminals A and B and the resistors R1 to R15. Only one of the switching circuits SW0 to SW15 is selected by the corresponding selection signal SELn (D0 to D15) outputted from the decoder 4.

The switching circuits SWn are respectively formed by PMOS and NMOS transistors Tr1 and Tr2, and are connected in parallel between the connection node Nn of the resistor circuit and the output terminal C. The output terminal C is connected to a non-inverting terminal of an op-amp OP2. The transistors Tr1 and Tr2 forming each of the switching circuits SWn are controlled by a logic circuit including by a logic circuit 22, a logic circuit 23 and a latch circuit 21 as described later.

The logic circuit 22 includes an inverter circuit IV11, a clocked inverter circuits CIV12 and CIV13 and an inverter circuit IV14. One of the selection signals Sn based on the selection signals SELn outputted from the decoder 4 via the latch circuit 21 is supplied to an input terminal of the inverter circuit IV11. An output from the inverter circuit IV11 is supplied to a gate GP of the PMOS transistor Tr1, and supplied to input terminals of the clocked inverter circuits CIV12 and CIV13, respectively.

The clocked inverter circuits CIV12 and CIV13 are operated exclusively by the control clock signals φn and /φn, and an output from the clocked inverter circuit CIV12 when the clocked inverter circuit CIV12 operates (φ=“H”) is supplied to a gate GN of the NMOS transistor Tr2 via the inverter circuit IV14. An output from the clocked inverter circuit CIV13 when the clocked inverter circuit CIV13 operates (φ=“L”) is supplied to the gate GN of the NMOS transistor Tr2. The control clocks φn and /φn are generated depending on a value of the foregoing selection signal Tn as shown in FIG. 17. In addition, for example, the clocked inverter circuit CIV12 can be formed as a circuit shown in FIG. 19. When φ=“H”, the clocked inverter circuit CIV12 operates as an ordinary inverter, and when φ=“L”, the clocked inverter circuit CIV12 has a high impedance state.

During the normal operation (in mode 1: when the test mode selection signal TEST is low in level), only one output signal exclusively selected among m pieces of output signals Sn which are outputted from the latch circuit based on the selection signal SELn is rendered high in level, and all of the other output signals Sn are rendered low in level. Furthermore, all of the m selection signals Tn that are a logical product (AND) output of the test mode selection signal TEST and the selection signal SELn are rendered low in level. Therefore, the control clock φ is rendered low in level, and all of the clocked inverter circuits CIV13 operate exclusively for the clocked inverter circuit CIV12.

Accordingly, the gate potential of the PMOS transistor Tr1 in one switching circuit selected by the selection signal SELn is rendered low in level (ground potential GND), and the gate potential of the NMOS transistor Tr2 is rendered high in level (power source voltage VDD). Therefore, both of the transistors Tr1 and Tr2 are turned ON.

Furthermore, in the switching circuits which are not selected, because the control clock φ and the output signal Sn from the latch circuit 21 based on the selection signal SELn are rendered together low in level, the gate potential of the PMOS transistor is rendered high in level, and the gate potential of the NMOS transistor is rendered low in level. Thus, both of these transistors have the open-circuit state.

During the test for the switching circuit, the test mode selection signal TEST is rendered high in level. Among m pieces of selection signals Tn that are a logical product (AND) output of the test mode selection signal TEST and the selection signal SELn, only one selection signal Tn corresponding to a switching circuit exclusively selected by the selection signal SELn is rendered high in level, and all of the other selection signals Tn are rendered low in level. Therefore, the control clock φ alone supplied to one switching circuit selected becomes high in level, and only the clocked inverter circuit CIV12 supplied with this control clock exclusively operates for the clocked inverter circuit CIV13. Furthermore, as to the other remaining switching circuits, because all of the control clocks φ are rendered low in level, the clocked inverter circuit CIV13 operates for the clocked inverter circuit CIV12 exclusively.

The test (in mode 2) of the PMOS transistor is performed in a state where the test mode selection signal TEST is rendered high in level in the above described manner. In one switching circuit selected by the selection signal SELn, because the control clock φ and the output signal Sn from the latch circuit 21 are together high in level, the gate potentials of the PMOS and NMOS transistors Tr1 and Tr2 are rendered low in level. Accordingly, only the PMOS transistor Tr1 can be rendered in a turning-ON state, and the NMOS transistor Tr2 can be rendered in a turning-OFF state.

Furthermore, in the switching circuits which are not selected, because the control clock φ and the output signal Sn from the latch circuit 21 are rendered together low in level, the gate potential of the PMOS transistor Tr1 is rendered high in level, and the gate potential of the NMOS transistor Tr2 is rendered low in level. Thus, both of these transistors have a turning-OFF state. Specifically, by rendering the test mode selection signal TEST high in level, the PMOS transistor Tr1 can be tested.

The test (in mode 3) of the NMOS transistor is performed by inputting a high level reset signal (“H”) to the latch reset terminal R of the latch circuit 21 in a state where the test mode selection signal TEST is rendered high in level. When the high level reset signal (“H”) is inputted to the latch reset terminal R, all of outputs from the latch circuit 21 are rendered low in level regardless of a value of the selection signal SELn as described above, and outputted to the volume circuit 20.

In one switching circuit selected by the selection signal SELn, the gate potentials of the PMOS and NMOS transistors Tr1 and Tr2 are together rendered high in level, because the control clock φ and the output signal Sn from the latch circuit 21 are rendered high in level. Accordingly, the PMOS transistor Tr1 can be rendered in a turning-OFF state, and only the NMOS transistor Tr2 is rendered in a turning-ON state.

Furthermore, in the switching circuits which are not selected, the gate potential of the PMOS transistor Tr1 is rendered high in level and the gate potential of the NMOS transistor is rendered low in level., because the control clock φ and the output signal Sn from the latch circuit 21 are rendered together low in level. Thus, both of these transistors are in the open-circuit state. Specifically, in the test mode, by inputting the high level reset signal to the latch reset terminal R of the latch circuit 21, only the NMOS transistor Tr2 can be tested.

As described above, the transistors Tr1 and Tr2 in the forming circuit SWn can be controlled by the logic circuit 22, the logic circuit 23 and the latch circuit 21.

According to the fourth embodiment, the PMOS and NMOS transistors Tr1 and Tr2 are selected by the selection signal SELn and the test mode selection signal TEST outputted from the first decoder 4 and the latch reset signal. According to this fourth embodiment, it is possible to further reduce a circuit scale compared to the logic circuit 12 of the first embodiment, because the clocked inverter is used in the logic circuit 22 of each switching circuit SWn,

Furthermore, in this fourth embodiment, influences of a plurality of transient state changes of the decoder output signals to be inputted to the volume can be removed and a control of the volume can be performed with a higher precision compared to the first embodiment, because the latch circuit which latches m pieces of output signals from the decoder circuit and then arranges output timings of them to output them is provided between the decoder circuit and the volume circuit.

However, the fourth embodiment is not limited to this. In addition to the fourth embodiment, the first to third embodiments may be adopted.

As a matter of course, various modifications can be embodied without departing from the scope of the present invention.

As described above in detail, according to the embodiments of the present invention, the plurality of transistors forming the switching circuit can be individually tested, making it possible to provide the electronic volume circuit capable of detecting all failures of the plurality of transistors forming the switching circuit.

Furthermore, according to the embodiments of the present invention, it is possible to provide the electronic volume circuit capable of suppressing an increase in a test cost and measuring the attenuation rate of the resistor precisely.

While there has been illustrated and described embodiments of the present invention, it will be understood by those skilled in the art that various changes and modifications may be made, and equivalents may be substituted for devices thereof without departing from the true scope of the invention. In addition, many modifications may be made to adapt a particular situation or material to the teaching of the present invention without departing from the central scope thereof. Therefore, it is intended that this invention not be limited to the particular embodiment disclosed, but that the invention includes all embodiments falling within the scope of the appended claims.

What is claimed is:

1. An electronic volume circuit comprising:
a resistor circuit including a plurality of resistors connected in series;
a plurality of switching circuits, each including a first transistor of a first conductivity type and a second transistor of a second conductivity type having a current path connected in parallel to said first transistor, and each switching circuit being connected between an output terminal of said electronic volume circuit and a corresponding connection node of said resistor circuit;
a decoder circuit configured to exclusively select one of the plurality of switching circuits; and
a logic circuit configured to select one of said first and second transistors in the switching circuit selected by said decoder circuit during a testing operation.

2. The electronic volume circuit according to claim 1, wherein the logic circuit comprises:
a circuit configured to receive a first selection signal output from the decoder circuit for selecting said one switching circuit, to receive a second selection signal for selecting said first transistor, and to receive a third selection signal for selecting said second transistor, and to select one of said first and second transistors in accordance with said first, second and third selection signals during said testing operation.

3. The electronic volume circuit according to claim 1, further comprising:
a first amplifier circuit having an input terminal supplied with an input signal, and an output terminal connected to one end of said resistor circuit; and
a second amplifier circuit having an input terminal connected to an output terminal of each of the plurality of switching circuits.

4. The electronic volume circuit according to claim 2, further comprising:
a first amplifier circuit including an input terminal supplied with an input signal, and an output terminal connected to one end of said resistor circuit; and
a second amplifier circuit including an input terminal connected to an output terminal of each of the plurality of switching circuits.

5. The electronic volume circuit according to claim 1, further comprising:
a first amplifier circuit including a first input terminal supplied with an input signal, a second input terminal supplied with a control signal, and an output terminal connected to one end of said resistor circuit, said output terminal being set to a high impedance in accordance with said control signal during said testing operation; and
a second amplifier circuit including an input terminal connected to an output terminal of each of the plurality of switching circuits.

6. The electronic volume circuit according to claim 2, further comprising:
a first amplifier circuit including a first input terminal supplied with an input signal, a second input terminal supplied with a control signal, and an output terminal connected to one end of said resistor circuit, said output terminal being set to a high impedance in accordance with said control signal during said testing operation; and
a second amplifier circuit including an input terminal connected to an output terminal of each of the plurality of switching circuits.

7. The electronic volume circuit according to claim 5, further comprising:
a first potential supply circuit configured to supply a first potential to said first input terminal of said first amplifier circuit during said testing operation; and
a second potential supply circuit configured to supply said first potential to another end of said terminal of said resistor circuit during said testing operation.

8. The electronic volume circuit according to claim 6, further comprising:
a first potential supply circuit configured to supply a first potential to said first input terminal of said first amplifier circuit during said testing operation; and
a second potential supply circuit configured to supply said first potential to another end of said terminal of said resistor circuit during said testing operation.

9. The electronic volume circuit according to claim 1, further comprising:
a third potential supply circuit connected to at least one connection node between the resistors in said resistor circuit, and configured to supply a potential to said at least one connection node during said testing operation, which is equal to a potential supplied to one end of said resistor circuit.

10. The electronic volume circuit according to claim 2, further comprising:
a third potential supply circuit connected to at least one connection node between the resistors in said resistor circuit, and configured to supply a potential to said at least one connection node during said testing operation, which is equal to a potential supplied to one end of said resistor circuit.

11. The electronic volume circuit according to claim 9, further comprising:
a first amplifier circuit including an input terminal supplied with an input signal and an output terminal connected to one end of said resistor circuit; and
a second amplifier circuit including an input terminal connected to an output terminal of each of the plurality of switching circuits.

12. The electronic volume circuit according to claim 10, further comprising:
a first amplifier circuit including an input terminal supplied with an input signal and an output terminal connected to one end of said resistor circuit; and
a second amplifier circuit including an input terminal connected to an output terminal of each of the plurality of switching circuits.

13. The electronic volume circuit according to claim 1, wherein said decoder circuit further comprises:
a circuit configured to decode a first selection signal and to output a second selection signal so as to exclusively select one of said plurality of switching circuits, and
wherein the logic circuit comprises:
a latch circuit including a gate terminal and a reset terminal, and configured to latch and to output said second selection signal as a third selection signal when a gate signal is input to said gate terminal and to output a first level signal as said third selection signal when a reset signal is input to said reset terminal;
a first logic circuit configured to generate a fifth selection signal in response to said second selection signal and a fourth selection signal representing a testing mode; and
a second logic circuit configured to determine a potential supplied to respective gates of said first and second transistors in response to said third selection signal and said fifth selection signal.

14. The electronic volume circuit according to claim 13, wherein said first logic circuit further comprises a logic AND circuit configured to output a logical AND of said second selection signal and said fourth selection signal, and
wherein the second logic circuit comprises at least two clocked inverter circuits configured to operate exclusively in response to said fifth selection signal and to output one of said third selection signal inputted thereto or a inverting signal of said third selection signal.

15. The electronic volume circuit according to claim 13, further comprising:
a first amplifier circuit including an input terminal supplied with an input signal and an output terminal connected to one end of said resistor circuit; and
a second amplifier circuit including an input terminal connected to an output terminal of each of the plurality of switching circuits.

16. The electronic volume circuit according to claim 13, further comprising:
a first amplifier circuit including a first input terminal supplied with an input signal, a second input terminal supplied with a control signal, and an output terminal connected to one end of said resistor circuit, said output terminal being set to a high impedance in accordance with said control signal during said testing operation;
a second amplifier circuit including an input terminal connected to an output terminal of each of the plurality of switching circuits;
a first potential supply circuit configured to supply a first potential to an input terminal of said first amplifier circuit; and
a second potential supply circuit configured to supply said first potential to another end of the terminal of said resistor circuit.

17. The electronic volume circuit according to claim 13, further comprising:
a third potential supply circuit connected to at least one connection node between the resistors in said resistor circuit, and configured to supply a predetermined potential to said at least one connection node during said testing operation.

18. An electronic volume circuit comprising:
a resistor circuit including a plurality of resistors connected in series;
a plurality of switching circuits, each including a first transistor of a first conductivity type and a second transistor of a second conductivity type having a current path connected in parallel to said first transistor, and each switching circuit being connected between an output terminal of said electronic volume circuit and a corresponding connection node of said resistor circuit;
a decoder circuit configured to decode a first selection signal and to output a second selection signal so as to exclusively select one of said plurality of switching circuits;
a latch circuit including a gate terminal and a reset terminal, and configured to latch and to output said second selection signal as a third selection signal in response to a gate signal inputted to said gate terminal and to output a first level signal as a third selection signal in response to a reset signal inputted to said reset terminal;
a first logic circuit configured to generate a fifth selection signal in response to said second selection signal and a fourth selection signal representing a testing mode; and
a second logic circuit configured to determine a potential supplied to respective gates of said first and second transistors in response to said third selection signal and said fifth selection signal.

19. The electronic volume circuit according to claim 18, wherein the first logic circuit comprises a logical product circuit configured to output a logical product of said second selection signal and said fourth selection signal, and
wherein the second logic circuit further comprises at least two clocked inverter circuits configured to operate exclusively in response to said fifth selection signal and to output said third selection signal inputted thereto or a signal obtained by inverting said third selection signal.

20. The electronic volume circuit according to claim 19, further comprising:
a first amplifier circuit including an input terminal supplied with an input signal and an output terminal connected to one end of said resistor circuit; and
a second amplifier circuit including an input terminal connected to an output terminal of each of the plurality of switching circuits.
